(19) United States
(12) Patent Application Publication
(10) Pub. No.: US 2012/0049354 A1
(43) Pub. Date: Mar. 1, 2012

(54) SEMICONDUCTOR DEVICE AND METHOD OF FORMING THE SAME

(75) Inventors: Emi SAWAYAMA, Tokyo (JP); Masahiro Yamaguchi, Tokyo (JP)

(73) Assignee: Elpida Memory, Inc.

(21) Appl. No.: 13/219,155

(22) Filed: Aug. 26, 2011

(30) Foreign Application Priority Data
Aug. 27, 2010 (JP) 2010-191106
Feb. 24, 2011 (JP) 2011-038263

(51) Int. Cl. H01L 23/498; H01L 23/48

(52) U.S. Cl. 257/737; 257/774; 257/E23.068; 257/E23.011

(57) ABSTRACT

A semiconductor device includes a wiring board, a first semiconductor chip disposed over the wiring board, a stack of second semiconductor chips disposed over the first semiconductor chip; and a first connection structure connecting the first semiconductor chip and the stack of second semiconductor chips. The first connection structure includes first and second connection electrodes disposed on the first semiconductor chip and a closest second semiconductor chip of the stack, respectively. The closest second semiconductor chip is closest to the first semiconductor chip. A bonding material bonds the first and second connection electrodes.

### BACKGROUND OF THE INVENTION

1. Field of the Invention

The disclosure relates to a semiconductor device and to a method for manufacturing the semiconductor device.

Priorities are claimed on Japanese Patent Applications Nos. 2010-191106, filed Aug. 27, 2010 and 2011-38263, filed Feb. 24, 2011, the contents of which are incorporated herein by reference.

2. Description of the Related Art

In recent years, continuing advances in the level of semiconductor chip integration have been accompanied by an increase in chip size, and advances in microfine interconnects and multilevel structures. Also, to achieve high-density packaging, it is necessary to use smaller and thinner packages.

Art related to MCPs (Multichip Packages), in which a plurality of semiconductor chips are mounted with high density on a single wiring substrate, has been developed to meet such demands. More specifically, a CoC (Chip-On-Chip) type semiconductor package mounting a chip stack onto one surface of a wiring substrate, in which semiconductor chips having through electrodes known as TSVs (Through Silicon Vias) are stacked, has gained attention. These are disclosed in Japanese Patent Application Publication No. JPA 2007-214220.

### SUMMARY

In an embodiment, a semiconductor device may include, but is not limited to, a wiring board, a first semiconductor chip disposed over the wiring board; a stack of second semiconductor chips disposed over the first semiconductor chip; and a first connection structure connecting the first semiconductor chip and the stack of second semiconductor chips. The first connection structure may include, but is not limited to, first and second connection electrodes disposed on the first semiconductor chip and a closest second semiconductor chip of the stack, respectively, the closest second semiconductor chip being closest to the first semiconductor chip, and a bonding material bonding the first and second connection electrodes.

In another embodiment, a semiconductor device may include, but is not limited to, a wiring board including a plurality of pad electrodes thereon; a first semiconductor chip including a plurality of first bump electrodes on a first surface, a plurality of second bump electrodes on a second surface opposed to the first surface, and a plurality of first through electrodes electrically coupled the first bump electrodes to the second bump electrodes, and the first semiconductor chip mounted over the wiring board so that the first bump electrodes are electrically coupled to the pad electrodes of the wiring board; a chip stack including a plurality of second semiconductor chips that are stacked one another, the chip stack including a plurality of third bump electrodes on lowermost one of the second semiconductor chips, and the chip stack mounted over the first semiconductor chip so that the lowermost one of the second semiconductor chips faces the first semiconductor chip; and a plurality of first bonding materials provided between the plurality of second bump electrodes and the plurality of third bump electrodes, the plurality of first bonding materials bonding the plurality of second bump electrodes and the plurality of third bump electrodes.

In still one embodiment, a semiconductor device may include, but is not limited to, a first semiconductor chip, a first connection electrode on the first semiconductor chip, a second semiconductor chip stacked over the first semiconductor chip, a second connection electrode on the second semiconductor chip, and a first bonding material between the first and second connection electrodes. The first bonding material bonds the first and second connection electrodes. At least one of the second and third bump electrodes has at least a depression which is filled with the first bonding material.

In yet another embodiment, a method of forming a semiconductor device may include, but is not limited to, forming a stack of first semiconductor chips; and bonding, via a plurality of first bonding materials, a plurality of first connection electrodes of the first semiconductor chip included in the stack to a plurality of second connection electrodes of a second semiconductor chip.

### BRIEF DESCRIPTION OF THE DRAWINGS

The above features and advantages of embodiments of the present invention will be more apparent from the following description of certain preferred embodiments taken in conjunction with the accompanying drawings, in which:

FIG. 1A is a fragmentary cross sectional view illustrating a semiconductor device in accordance with an embodiment of the present invention;

FIG. 1B is a fragmentary enlarged view illustrating a connection structure between two adjacent semiconductor chips included in a stack of semiconductor chips included in the semiconductor device of FIG. 1;

FIG. 2A is a fragmentary cross sectional view illustrating a step involved in a method of forming the semiconductor device shown in FIG. 1A;

FIG. 2B is a fragmentary cross sectional view illustrating a step, subsequent to the step of FIG. 2A, involved in the method of forming the semiconductor device shown in FIG. 1A;

FIG. 2C is a fragmentary cross sectional view illustrating a step, subsequent to the step of FIG. 2B, involved in the method of forming the semiconductor device shown in FIG. 1A;

FIG. 3A is a fragmentary cross sectional view illustrating a step, subsequent to the step of FIG. 2C, involved in the method of forming the semiconductor device shown in FIG. 1A;

FIG. 3B is a fragmentary cross sectional view illustrating a step, subsequent to the step of FIG. 3A, involved in the method of forming the semiconductor device shown in FIG. 1A;

FIG. 3C is a fragmentary cross sectional view illustrating a step, subsequent to the step of FIG. 3B, involved in the method of forming the semiconductor device shown in FIG. 1A;

FIG. 3D is a fragmentary cross sectional view illustrating a step, subsequent to the step of FIG. 3C, involved in the method of forming the semiconductor device shown in FIG. 1A;

FIG. 4A is a fragmentary cross sectional view illustrating a step, subsequent to the step of FIG. 3D, involved in the method of forming the semiconductor device shown in FIG. 1A;

FIG. 4B is a fragmentary cross sectional view illustrating a step, subsequent to the step of FIG. 4A, involved in the method of forming the semiconductor device shown in FIG. 1A;

FIG. 4C is a fragmentary cross sectional view illustrating a step, subsequent to the step of FIG. 4B, involved in the method of forming the semiconductor device shown in FIG. 1A;

FIG. 5A is a fragmentary cross sectional view illustrating a step, subsequent to the step of FIG. 4C, involved in the method of forming the semiconductor device shown in FIG. 1A;

FIG. 5B is a fragmentary cross sectional view illustrating a step, subsequent to the step of FIG. 5A, involved in the method of forming the semiconductor device shown in FIG. 1A;

FIG. 6A is a fragmentary cross sectional view illustrating a step, subsequent to the step of FIG. 5B, involved in the method of forming the semiconductor device shown in FIG. 1A;

FIG. 6B is a fragmentary cross sectional view illustrating a step, subsequent to the step of FIG. 6A, involved in the method of forming the semiconductor device shown in FIG. 1A;

FIG. 7A is a fragmentary cross sectional view illustrating a step, subsequent to the step of FIG. 6B, involved in the method of forming the semiconductor device shown in FIG. 1A;

FIG. 7B is a fragmentary cross sectional view illustrating a step, subsequent to the step of FIG. 7A, involved in the method of forming the semiconductor device shown in FIG. 1A;

FIG. 7C is a fragmentary cross sectional view illustrating a step, subsequent to the step of FIG. 7B, involved in the method of forming the semiconductor device shown in FIG. 1A;

FIG. 8 is a fragmentary cross sectional view illustrating a step, subsequent to the step of FIG. 7C, involved in the method of forming the semiconductor device shown in FIG. 1A;

FIG. 9 is a fragmentary cross sectional view illustrating a step, subsequent to the step of FIG. 8, involved in the method of forming the semiconductor device shown in FIG. 1A;

FIG. 10 is a fragmentary cross sectional view illustrating a step, subsequent to the step of FIG. 9, involved in the method of forming the semiconductor device shown in FIG. 1A;

FIG. 11A is a fragmentary cross sectional view illustrating a step involved in a modified method of forming the semiconductor device shown in FIG. 1A;

FIG. 11B is a fragmentary cross sectional view illustrating a step, subsequent to the step of FIG. 11A, involved in the modified method of forming the semiconductor device shown in FIG. 1A;

FIG. 11C is a fragmentary cross sectional view illustrating a step, subsequent to the step of FIG. 11B, involved in the modified method of forming the semiconductor device shown in FIG. 1A; and

FIG. 11D is a fragmentary cross sectional view illustrating a step, subsequent to the step of FIG. 11C, involved in the modified method of forming the semiconductor device shown in FIG. 1A.

### DETAILED DESCRIPTION OF THE PREFERRED EMBODIMENTS

Before describing embodiments of the present invention, the related art will be explained in detail, in order to facilitate the understanding of embodiments of the present invention.

In a CoC type semiconductor package as described above, investigations are conducted regarding of stack-mounting a logic chip forming, over a multichip stack formed by stacking a plurality of memory chips such as DRAMs (dynamic random access memory circuits), for example, logic circuitry to control the memory chips.

Because of the restrictions regarding the electrode materials forming the mutual connection terminals (bump electrodes) between memory chips and the logic chips, which are of different types of semiconductor chips, there is a risk of bad connections between these connection terminals.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In another embodiment, a semiconductor device may include, but is not limited to, a wiring board, a first semiconductor chip disposed over the wiring board; a stack of second semiconductor chips disposed over the first semiconductor chip; and a first connection structure connecting the first semiconductor chip and the stack of second semiconductor chips. The first connection structure may include, but is not limited to, first and second connection electrodes disposed on the first semiconductor chip and a closest second semiconductor chip of the stack, respectively, the closest second semiconductor chip being closest to the first semiconductor chip, and a bonding material bonding the first and second connection electrodes.

In some cases, at least one of the second and third bump electrodes may have at least a depression which is filled with the bonding material.

In some cases, the first bonding material may include, but is not limited to, a solder.

In some cases, the first semiconductor chip may be different in type from the second semiconductor chip.

In some cases, the first semiconductor chip may be a logic chip, and the second semiconductor chip may be a memory chip which is larger in dimension than the logic chip.

In some cases, the semiconductor device may further include, but is not limited to, a third connection electrode on the first semiconductor chip, a first through electrode penetrating the first semiconductor chip. The first through electrode connects the first and third connection electrodes. The first and third connection electrodes are disposed on opposite surfaces of the first semiconductor chip.

In some cases, the semiconductor device may further include, but is not limited to, an adhesive material between the wiring board and the first semiconductor chip.

In some cases, the semiconductor device may further include, but is not limited to, a first sealing material that fills a first gap between the first and second semiconductor chips and a second gap between the second and third semiconductor chips, and a second sealing material covering the adhesive material and the first sealing material.

In another embodiment, a semiconductor device may include, but is not limited to, a first semiconductor chip, a first connection electrode on the first semiconductor chip, a second semiconductor chip stacked over the first semiconductor chip, a second connection electrode on the second semiconductor chip, and a first bonding material between the first and second connection electrodes. The first bonding material bonds the first and second connection electrodes. At least one of the first and second connection electrodes may have at least a depression which is filled with the first bonding material.

In some cases, the depression may be positioned at a center of the at least one of the first and second connection electrodes.

In some cases, the semiconductor device may further include, but is not limited to, a wiring board on which the first semiconductor chip is stacked.

In some cases, the third connection electrode may be greater in height than the first connection electrode.

In some cases, the semiconductor device may further include, but is not limited to, a fourth connection electrode on the wiring board, and a second bonding material between the third and fourth connection electrodes. The second bonding material bonds the third and fourth connection electrodes.

In some cases, the semiconductor device may further include, but is not limited to, a third semiconductor chip stacked on the second semiconductor chip, a fifth connection electrode on the second semiconductor chip, the second and fifth connection electrodes being disposed on opposite surfaces of the second semiconductor chip, a sixth connection electrode on the third semiconductor chip, the sixth connection electrode being in contact with the fifth connection electrode, and a second through electrode penetrating the second semiconductor chip. The second through electrode connects the second and fifth connection electrodes.

In still another embodiment, a semiconductor device may include, but is not limited to, a wiring board; a plurality of pad electrodes on the wiring board; a first semiconductor chip stacked over the wiring board; a plurality of first bump electrodes on a first surface of the first semiconductor chip, the plurality of first bump electrodes being connected to the plurality of pad electrodes; a plurality of first through electrodes penetrating the first semiconductor chip; a plurality of second bump electrodes on a second surface of the first semiconductor chip; a second semiconductor chip stacked over the first semiconductor chip, the second semiconductor chip being different in size from the first semiconductor chip; a plurality of third bump electrodes on a first surface of the second semiconductor chip; and a plurality of first bonding materials between the plurality of second bump electrodes and the plurality of third bump electrodes, the plurality of first bonding materials bonding the plurality of second bump electrodes and the plurality of third bump electrodes.

In some cases, at least one of the second and third bump electrodes may have at least a depression which is filled with the first bonding material.

In some cases, the semiconductor device may further include, but is not limited to, a plurality of first through electrodes penetrating the first semiconductor chip, the plurality of first through electrodes connecting the plurality of first bump electrodes and the plurality of second bump electrodes; a plurality of fourth bump electrodes on a second surface of the second semiconductor chip; a plurality of second through electrodes penetrating the second semiconductor chip, the plurality of second through electrodes connecting the plurality of third bump electrodes and the plurality of fourth bump electrodes; a third semiconductor chip stacked over the second semiconductor chip; and a plurality of fifth bump electrodes on a first surface of the third semiconductor chip, the plurality of fifth bump electrodes being in contact with the plurality of fourth bump electrodes.

In some cases, the semiconductor device may further include, but is not limited to, a plurality of second bonding materials between the plurality of pad electrodes and the plurality of first bump electrodes, the plurality of second bonding materials bonding the plurality of pad electrodes and the plurality of first bump electrodes; an adhesive material between the wiring board and the first semiconductor chip; a first sealing material that fills a first gap between the first and second semiconductor chips and a second gap between the second and third semiconductor chips; a second sealing material covering the adhesive material and the first sealing material; and an external connection terminal on the wiring board.

In yet another embodiment, a method of forming a semiconductor device may include, but is not limited to, forming a stack of first semiconductor chips; and bonding, via a plurality of first bonding materials, a plurality of first connection electrodes of the first semiconductor chip included in the stack to a plurality of second connection electrodes of a second semiconductor chip.

In some cases, the method may further include, but is not limited to, forming at least a depression on at least one of the first and second connection electrodes before bonding, so that the at least depression is filled with the first bonding material.

In some cases, forming the stack of first semiconductor chips may include, but is not limited to, bonding the first semiconductor chips to each other through connection electrodes without any bonding materials.

In some cases, the method may further include, but is not limited to, bonding, to a mother wiring board, the second semiconductor chip bonded with the stack of first semiconductor chips.

In some cases, bonding the second semiconductor chip to the mother wiring board may include, but is not limited to, bonding, via a plurality of second bonding materials, a plurality of third connection electrodes of the second semiconductor chip to a plurality of fourth connection electrodes of the mother wiring board.

In some cases, the method may further include, but is not limited to, applying an adhesive material on the mother wiring board before bonding the mother wiring board through the adhesive material to the second semiconductor chip.

In some cases, the method may further include, but is not limited to, sealing the second semiconductor chip and the stack of first semiconductor chips with a first sealing member before bonding the mother wiring board to the second semiconductor chip.

In some cases, sealing with the first sealing member may include, but is not limited to, sealing the stack of first semiconductor chips with a first sealing member before bonding via the plurality of first bonding materials; and sealing a gap between the second semiconductor chip and the stack of first semiconductor chips with the first sealing member after bonding via the plurality of first bonding materials.

In some cases, sealing with the first sealing member may include, but is not limited to, sealing the stack of first semiconductor chips and a gap between the stack of first semiconductor chips after bonding via the plurality of first bonding materials.

In some cases, the method may further include, but is not limited to, sealing the mother wiring board, the first sealing member and the adhesive material with a second sealing member.

In some cases, the method may further include, but is not limited to, disposing a plurality of external electrodes on the mother wiring board.

In some cases, the method may further include, but is not limited to, cutting the mother wiring board into a plurality of wiring boards on which the stack of the first semiconductor chips and the second semiconductor chip are stacked.

### (Semiconductor Device)

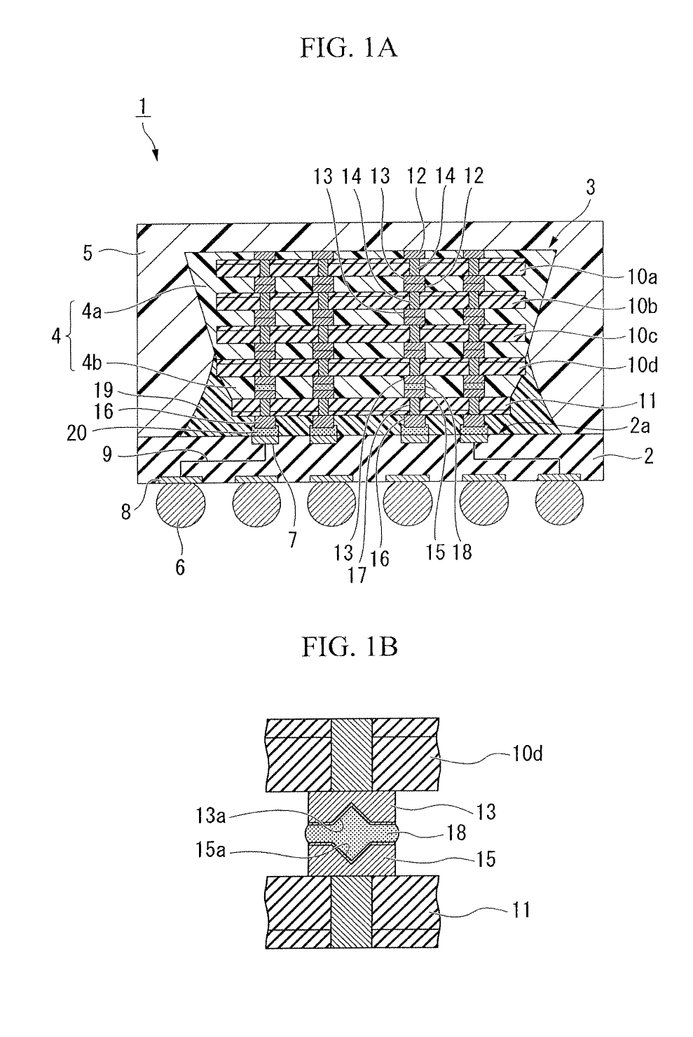

First, a CoC type semiconductor package 1 shown in FIG. 1A will be described as an example of a semiconductor device to which the present embodiment is applied. The semiconductor package 1, as shown in FIG. 1, by having an wiring substrate 2, a chip stack 3 mounted to one surface (top surface) of the wiring substrate 2, a first sealing element 4 covering the chip stack 3, a second sealing element 5 covering the first sealing element 4, and a plurality of solder balls (external connection terminals) 6 disposed on another surface of the wiring substrate 2, forms a package structure that is known as a BGA (ball grid array).

The wiring substrate 2 is made of a printed circuit board that is rectangular when seen in plan view manner, a mounting region 2a in which the chip stack 3 is mounted being provided in the center part of the upper surface of the wiring substrate 2. A plurality of pad electrodes (fifth connection terminals) 7 are provided in an arrangement on the mounting region 2a of the wiring substrate 2. A plurality of connection lands 8 are provided in an arrangement on another surface (lower surface) of the wiring substrate 2. The above-noted solder balls 6 are disposed over the connection lands 8. In addition, in the wiring substrate 2, vias (through electrodes) and interconnecting leads 9 (indicated schematically in FIG. 1A) such as interconnect patterns are provided to make electrical connections between pad electrodes 7 and the connection lands 8. The surface of the wiring substrate 2, with the exception of the pad electrodes 7 and connection lands 8, is covered with, for example, an insulating film (not shown) such as one of solder resist.

The chip stack 3 has a structure wherein, starting in sequence from the surface opposite the one surface of the wiring substrate 2, a plurality (four in this example) of memory chips (first semiconductor chips) 10a to 10d, such as DRAM (dynamic random access memory) circuits are formed and, thereover, a logic chip (second semiconductor chip) 11 of logic circuitry and the like that controls each of the memory chips 10a to 10d is stacked thereon.

Of the above, the plurality of memory chips 10a to 10d, in addition to appearing rectangular when seen in plan view manner, are smaller than the wiring substrate 2, and each has a plurality of first bump electrodes (first connection terminals) 12 on one surface thereof, a plurality of second bump electrodes (second connection terminals) 13 on the other surface thereof, and a plurality of through electrodes (TSVs) 14 making connection between the first bump electrodes 12 and the second bump electrodes 13. The plurality of memory chips 10a to 10d are stacked with respective one surfaces and other surfaces facing one another, with first bump electrodes 12 and second bump electrodes 13 bonded therebetween.

The logic chip 11, in addition to appearing rectangular when seen in plan view manner, are slightly smaller than the memory chips 10a to 10d, and have a plurality of third bump electrodes (third connection terminals) 15 on one surface thereof, a plurality of fourth bump electrodes (fourth connection terminals) 16 on the other surface thereof, and a plurality of through electrodes (TSVs) 17 making connection between the third bump electrodes 15 and the fourth bump electrodes 16. The fourth bump electrodes 16, by forming, for example, a copper pillar of approximately 30 μm, are formed to be taller than the third bump electrodes 15. By doing this, it is possible to maintain good bonding with the wiring substrate 2 even if there is warping of the logic chip 11.

The logic chip 11 is stacked so that one surface thereof opposes the other surface of the memory chip 10d below it, and the second bump electrodes 13 and the third bump electrodes 15 therebetween are bonded via a first bonding member 18.

The chip stack 3 is adhered and fixed to the mounting region 2a of the wiring substrate 2 via an adhesive member 19 that protrudes from between the opposing one surface of the wiring substrate 2 and the other surface of the logic chip 11. The fourth bump electrodes 16 and the pad electrodes 7 therebetween are bonded via a second bonding member 20. A wire bump may be used as the second bonding member 20.

The first sealing element 4 seals the chip stack 3 by a first underfilling material 4a that fills in each of the gaps between the plurality of memory chips 10a to 10d, and a second underfilling material 4b that fills in the gap between the logic chip 11 and the memory chip 10d.

The second sealing element 5, by a molding resin that covers the entire chip stack 3 sealed by the first sealing element 4, seals the entire of the one surface of the wiring substrate 2.

In the semiconductor package 1, when stacking the plurality of memory chips 10a to 10d with the first bump electrodes 12 and the second bump electrodes 13 therebetween, from the standpoint of connectivity between the first bump electrodes 12 and the second bump electrodes 13, first bump electrodes 12, for example, in which an SnAg layer is formed on the surface of copper, and second bump electrodes 13, in which an NiAu layer is formed on the surface of copper, are used. By using a bonding tool to apply a load while heating to approximately 300° C., the first bump electrodes 12 and the second bump electrodes 13 are bonded by thermal bonding (flip-chip bonding).

When stacking the plurality of memory chips 10a to 10d by bonding the first bump electrodes 12 and the second bump electrodes 13 therebetween, while using an electrode material for the first bump electrodes 12 that is thermally melted by a bonding tool, an electrode material having a melting point that is higher than that is used as the second bump electrodes 13. By doing this, at the time of thermal bonding, even if the first bump electrodes 12 that are heated by a high-temperature bonding tool reach the melting point, because the second bump electrode 13 does not melt, it is possible to thermally bond the first bump electrodes 12 and the second bump electrodes 13, without adhesion to the bonding tool.

The logic chip 11, in contrast to the above-described memory chips 10a to 10d, does not have a multilevel stacked configuration, and uses third bump electrodes 15 and fourth bump electrodes 16 in which, for example, an NiAu layer is formed on the surface of copper. When stacking the logic chip 11 on the top of the above-noted plurality of memory chips 10a to 10d, therefore, the third bump electrodes 15 of the logic chip 11 and the second bump electrodes 13 of the memory chip 10d below are opposed to one another. However, these opposing second bump electrodes 13 and third bump electrodes 15 are both made of an electrode material in which an NiAu layer is formed on the surface of copper, making it difficult to directly bond them by thermal bonding using the above-described bonding tool.

Given this, in the semiconductor package 1 to which the present invention is applied, by the interposing of the first bonding members 18 between the third bump electrodes 15 of the logic chip 11 and the second bump electrodes 13 of the memory chip 10d therebelow, it is possible to achieve a good bonding of the second bump electrodes 13 and the third bump electrodes 15, in which an NiAu layer is formed on a copper surface. It is sufficient that the first bonding member 18 be of a material that enables a good bonding of the second bump electrodes 13 and the third bump electrodes 15 and, for example, a solder bump, may be used.

As noted above, in a semiconductor package 1 to which the present invention is applied, in a chip stack 3 in which a plurality of memory chips 10a to 10d are stacked, and a logic chip 11 is stacked thereover, when bonding the corresponding bump electrodes 13 and 15 between the memory chip 10d and the logic chip 11, which are of different types, by interposing the first bonding members 18 between the bump electrodes 13 and 15, it is possible to achieve a good bond between the bump electrodes 13 and 15 of the memory chip 10d and the logic chip 11, which are difficult to bond with heat, without a restriction on the electrode material or bonding method.

Also, in the present invention, as shown in FIG. 1B, depressions 13a and 15a may be provided in the mutually opposing surfaces of the second bump electrodes 13 and the third bump electrodes 15. The depressions 13a and 15a have shapes formed by causing the center parts of the mutually opposing surfaces of the second bump electrodes 13 and the third bump electrodes 15 to be depressed.

In this case, because a space that is sufficient to hold the first bonding member 18 therewithin is formed between the depressions 13a and 15a of the second bump electrodes 13 and the third bump electrodes 15, the first bonding members 18 (solder bumps), to which pressure is applied at the time of bonding the second bump electrodes 13 and the third bump electrodes 15, flow to the outside from between the bump electrodes 13 and 15, enabling prevention of the occurrence of bonding problems such as shorts.

If the spacing between the second bump electrode 13 and the third bump electrode 15 is too narrow, the solder bumps that form the first bonding members 18 experience a part having a high Au concentration, caused by diffusion of Au when bonding, this possibly leading to a loss of bond strength. In contrast, in the configuration in which the above-noted depressions 13a and 15a are provided, because a sufficient space is established between the second bump electrodes 13 and the third bump electrodes 15, the parts having an elevated Au concentration are reduced, and it is possible to increase the bond strength between the bump electrodes 13 and 15.

Additionally, in the solder bumps forming the first bonding member 18, because diffusion of copper at the time of bonding changes a part of the solder to a CuSn-based solder having a hard structure, although the flow from between the bump electrodes 13 and 15 is prevented, in a method in which solder is fed with the copper exposed, there are problems such as the oxidation of the copper, which make application difficult.

Although there is no particular restriction with regard to the method of forming the depressions 13a and 15a, it is possible, for example, after forming the above-noted through electrodes 14, to adjust the plating conditions for the subsequent plating and forming of the bump electrodes 13 and 15, so that the plating growth rate is greater in the area surrounding the center part thereof than it is in the center part, thereby forming depressions in the center parts of the bump electrodes 13 and 15.

The present invention may have a constitution in which at least one surface of the mutually opposing surfaces of the second bump electrodes 13 and the third bump electrodes 15 is provided with the above-noted depressions 13a and 15a.

Also, even in the case in which in the present invention a first bump electrode 12 and a second bump electrode 13 arranged between the plurality of memory chips 10a to 10d are bonded, the above-described method of bonding using solder bumps and also the method of bonding by providing depressions may be applied.

### (Method for Manufacturing a Semiconductor Package)

A method for manufacturing the semiconductor package 1 shown in FIG. 1A will be described as a method for manufacturing a semiconductor device to which the present invention is applied.

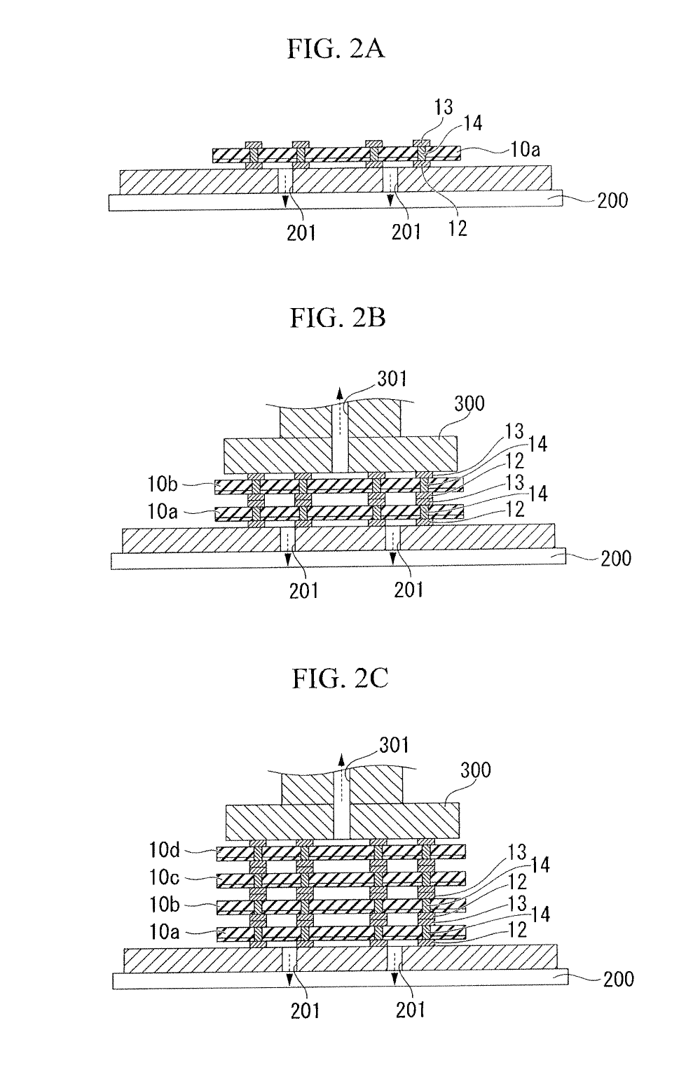

When manufacturing the above-noted semiconductor package 1, as shown in FIG. 2A to 2C, the above-noted plurality of memory chips 10a to 10d having a thickness of, for example, approximately 50 μm are caused to have their one and other surfaces in mutual opposition, and are stacked by the first bump electrodes 12 and second bump electrodes 13 therebetween being bonded.

As shown in FIG. 2A, the first memory chip 10a is placed onto a vacuum chuck stage 200, with the surface (one surface) of which having a plurality of first bump electrodes 12 formed thereon facing downward. The memory chip 10a is then chucked by a plurality of vacuum holes 201 provided in the vacuum chuck stage 200, thereby holding it onto the vacuum chuck stage 200.

In this condition, as shown in FIG. 2B, a bonding tool 300 is used to stack mount (flip-chip mount) the second memory chip 10b onto the first memory chip 10a. In this flip-chip mounting, a vacuum hole 301 provided in the bonding tool 300 vacuum chucks the second memory chip 10b as the bonding tool 300 holds the memory chip 10b, with the surface (one surface) on which is formed a plurality of first bump electrodes 12 facing downward.

The bonding tool 300 places the second memory chip 10b over the first memory chip 10a, while causing the one surface of the second memory chip 10b to oppose the other surface of the first memory chip 10a beneath it, with the positions of the first bump electrodes 12 and the second bump electrodes 13 therebetween aligned. In this condition, the bonding tool 300 applies a load while heating to approximately 300° C. to bond, by heat bonding (flip-chip bonding), the first bump electrodes 12, in which an SnAg layer is formed on a copper surface, and the second bump electrodes 13, in which an NiAu layer is formed on a copper surface.

When this bonding is done, not only a load, but ultrasonic waves as well may be applied.

By doing this, an electrical connection (flip-chip connection) is made between the first bump electrodes 12 and the second bump electrodes 13, and the second memory chip 10b is flip-chip mounted on top of the first memory chip 10a.

From this condition, as shown in FIG. 2C, by a method that is similar to the above-described flip-chip mounting of the second memory chip 10b on the first memory chip 10a, the third memory chip 10c is flip-chip mounted on top of the second memory chip 10b, and then the fourth memory chip 10d is flip-chip mounted on top of the third memory chip 10c.

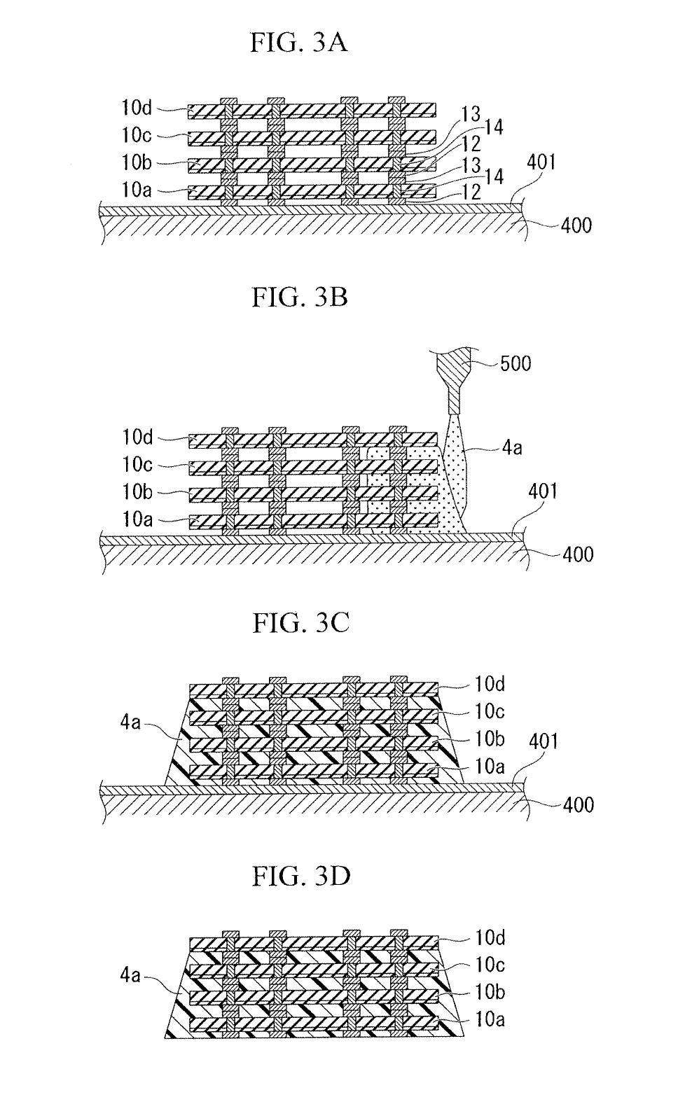

As shown in FIG. 3A to FIG. 3D, a first underfilling material 4a is filled between each gap in the stack formed by the stacking of the above-noted plurality of memory chips 10a to 10d, the first underfilling material 4a sealing the stack of memory chips 10a to 10d.

As shown in FIG. 3A, the stack of the memory chips 10a to 10d is placed on an application stage 400. An application sheet 401 made of a material such as a fluorine-based sheet or sheet to which a silicone-based adhesive material has been applied, for example, which has poor wetting by the first underfilling material 4a, is adhered over the surface of the application stage 400.

From this condition, as shown in FIG. 3B, a dispenser 500 that supplies the liquid-state first underfilling material 4a is used to apply the first underfilling material 4a toward the proximity of the edge parts of the stack of memory chips 10a to 10d. When this is done, the first underfilling material 4a, by capillary action, seeps into and fills the gaps formed between the memory chips 10a to 10d and the gap formed between the memory chip 10a and the application sheet 401. The first underfilling material 4a that oozes out of the gaps is suppressed from spreading on the surface by the application sheet 401. By doing this, it is possible to reduce the width of the first underfilling material 4a that oozes out of the gaps.

From this condition, as shown in FIG. 3C, by heating (curing) the first underfilling material 4a at a temperature of, for example, approximately 150° C., the first underfilling material 4a is caused to harden. After the first underfilling material 4a hardens, as shown in FIG. 3D, the stack of memory chips 10a to 10d that is sealed by the first underfilling material 4a is peeled away from the application sheet 401. As described above, because a material that has poor wetting by the first underfilling material 4a is used for the application sheet 401, the stack of the memory chips 10a to 10d that is sealed by the first underfilling material 4a can be easily peeled away from the application sheet 401.

The stack of memory chips 10a to 10d that is sealed by the first underfilling material 4a is then stored on a storage tray that is omitted from the drawing, and is transported to the next process. When sealing the stack of the memory chips 10a to 10d with the first underfilling material 4a, the stack of the memory chips 10a to 10d may be placed on an application sheet 401 that is spread over an annular fixture, the first underfilling material 4a being supplied to the inside of the annular fixture.

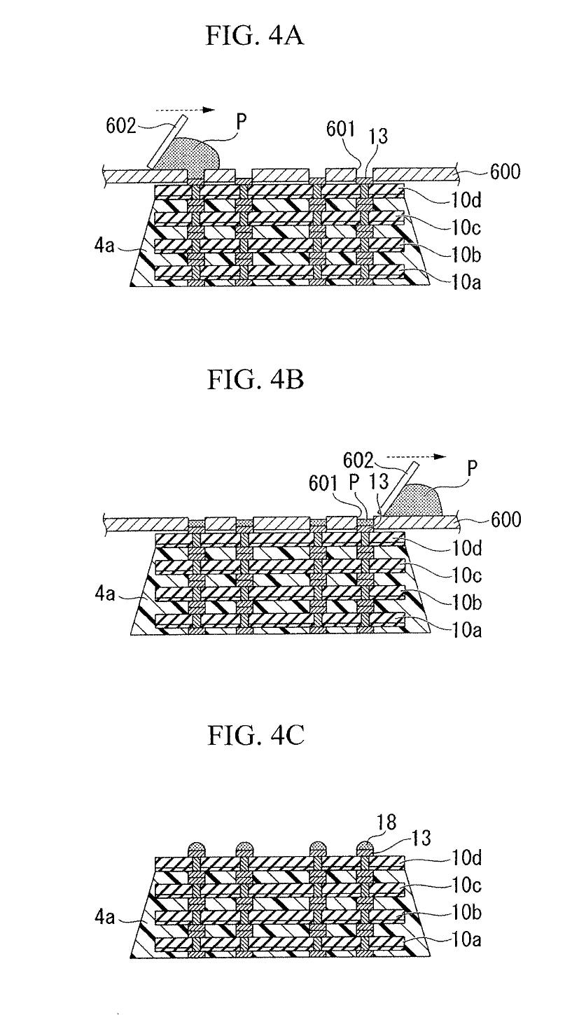

As shown in FIG. 4A to FIG. 4C, the first bonding member 18 is placed on the second bump electrode 13 of the memory chip 10d positioned on the uppermost layer of the above-noted stack.

As shown in FIG. 4A, a printing mask 600 is placed on the stack of the memory chips 10a to 10d sealed by the above-noted first underfilling material 4a. The printing mask 600 provides holes 601 at the positions corresponding to the second bump electrodes 13 of the memory chip 10d. After a solder paste P to serve as the above-noted first bonding material 18 is applied on the printing mask 600, screen printing is done using a squeegee 602.

As shown in FIG. 4A to 4B, as the squeegee 602 is moved on the printing mask 600, the solder paste P applied on the printing mask 600 is buried and placed into the holes 601. Subsequently, by reflowing at a prescribed temperature, as shown in FIG. 4C, the first bonding members 18 made of the above-noted solder bump are placed on the second bump electrodes 13 of the memory chip 10d.

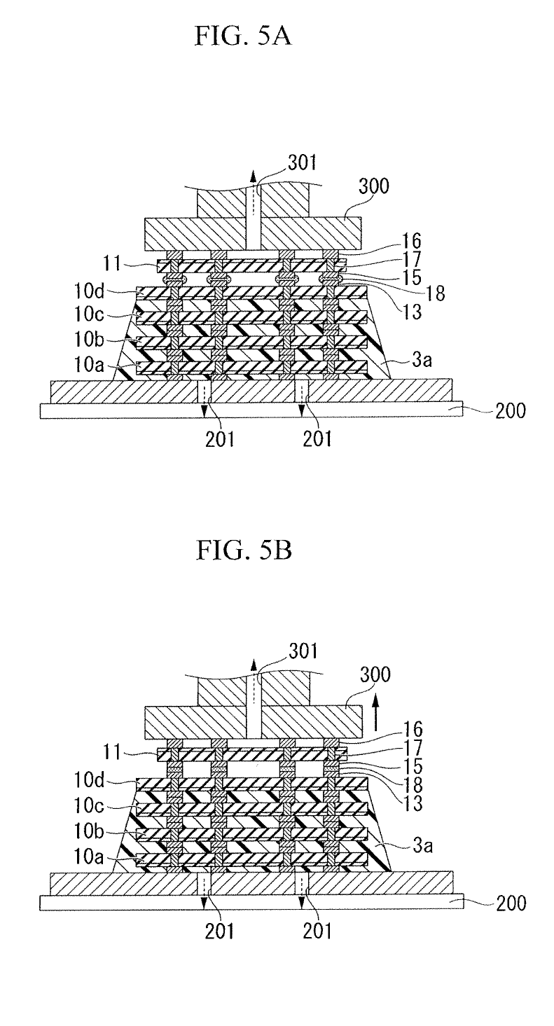

As shown in FIG. 5A, the above-noted logic chip 11 with a thickness of, for example, approximately 50 μm and the memory chip 10d therebelow are caused to have their one and other surfaces in mutual opposition, and are stacked by the second bump electrodes 13 and the third bump electrodes 15 therebetween being bonded, via the first bonding members 18.

In the condition in which the first memory chip 10a facing downward, the stack of the memory chips 10a to 10d which is sealed by the first underfilling material 4a is mounted on top of a vacuum chuck stage 200. The stack is chucked by a plurality of vacuum holes 201 of the vacuum chuck stage 200, thereby holding it onto the vacuum chuck stage 200.

From this condition, a bonding tool 300 is used to stack mount (flip-chip mount) the logic chip 11 on top of the memory chip 10d positioned at the uppermost (fourth) layer. In this flip-chip mounting, a vacuum hole 301 of the bonding tool 300 vacuum chucks the logic chip 11 as the bonding tool 300 holds the logic chip 11, with the surface (one surface) on which is formed a plurality of the third bump electrodes 15 facing downward.

The bonding tool 300 places the logic chip 11 over the fourth memory chip 10d, while causing the one surface of the logic chip 11 to oppose the other surface of the fourth memory chip 10d beneath it, with the positions of the second bump electrodes 13 and the third bump electrodes 15 therebetween aligned. In this condition, the bonding tool 300 applies a load while heating at a temperature of approximately 300° C. to bond by heat bonding (flip-chip bonding) the second bump electrodes 13, in which the NiAu layer is formed on the above-noted cupper surface, and the third bump electrodes 15, in which the NiAu layer is formed on the above-noted cupper surface, via the first bonding members (solder bumps) 18. When this bonding is done, not only a load, but ultrasonic waves as well may be applied.

By doing this, electrical connections (flip-chip connections) are made between the second bump electrodes 13 and the third bump electrodes 15, via the first bonding members (solder bumps) 18, and the logic chip 11 is flip-chip mounted on top of the fourth memory chip 10d.

Also, after the flip-chip mounding, as shown in FIG. 5B, the bonding tool 300 is move upwardly so that the gaps between the logic chip 11 and the fourth memory chip 10d are caused to widen. By doing this, even if the amount of the solder bumps which form the first bonding members 18 is made slightly larger, such a risk of spreading to adjacent bump electrodes 13 and 15 to cause shorts can be reduced. Also, by making the amount of the solder bumps slightly larger, good bonding can be maintained, even if there is warping of the logic chip 11.

In the present invention, as shown in FIG. 1B, the formation of the above-described depressions 13a and 15a on at least the one surface in mutual opposition to the second bump electrodes 13 and the third bump electrodes 15 enables further enhancement of the bonding strength, in the case in which the second bump electrodes 13 and the third bump electrodes 15 are bonded via the first bonding member 18.

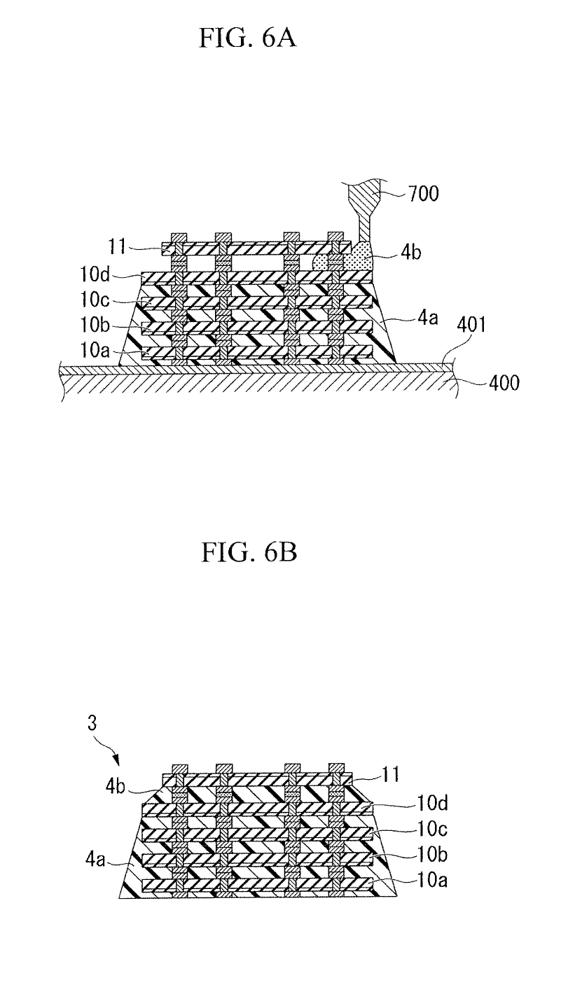

As shown in FIG. 6A and FIG. 6B, the second underfilling material 4b is filled into the gap between the logic chip 11 and the fourth memory chip 10d, the second underfilling material 4b sealing the logic chip 11.

As shown in FIG. 6A, after the stack of the above-noted memory chips 10a to 10d and the logic chip 11 is placed on top of an application sheet 401 of an application stage 400, a dispenser 700 that supplies the liquid-state second underfilling material 4b is used to apply the second underfilling material 4b toward the proximity of the edge parts of the logic chip 11.

When this is done, the second underfilling material 4b seeps into and fills the gaps formed between the logic chip 11 and the fourth memory chip 10d, by capillary action. Also, because the logic chip 11 is smaller than the fourth memory chip 10, the second underfilling material 4b that oozes out of the gaps remains on the memory chip 10d.

From this condition, by heating (curing) the second underfilling material 4b at a temperature of, for example, approximately 150° C., the second underfilling material 4b is caused to harden. After the second underfilling material 4b hardens, as shown in FIG. 6B, a chip stack 3 is peeled away from the above-noted application sheet 401. Also, in this case, the chip stack 3 can be easily peeled away from the application sheet 401. The chip stack 3 is then stored on a storage tray that is omitted from the drawing, and is transported to the next process.

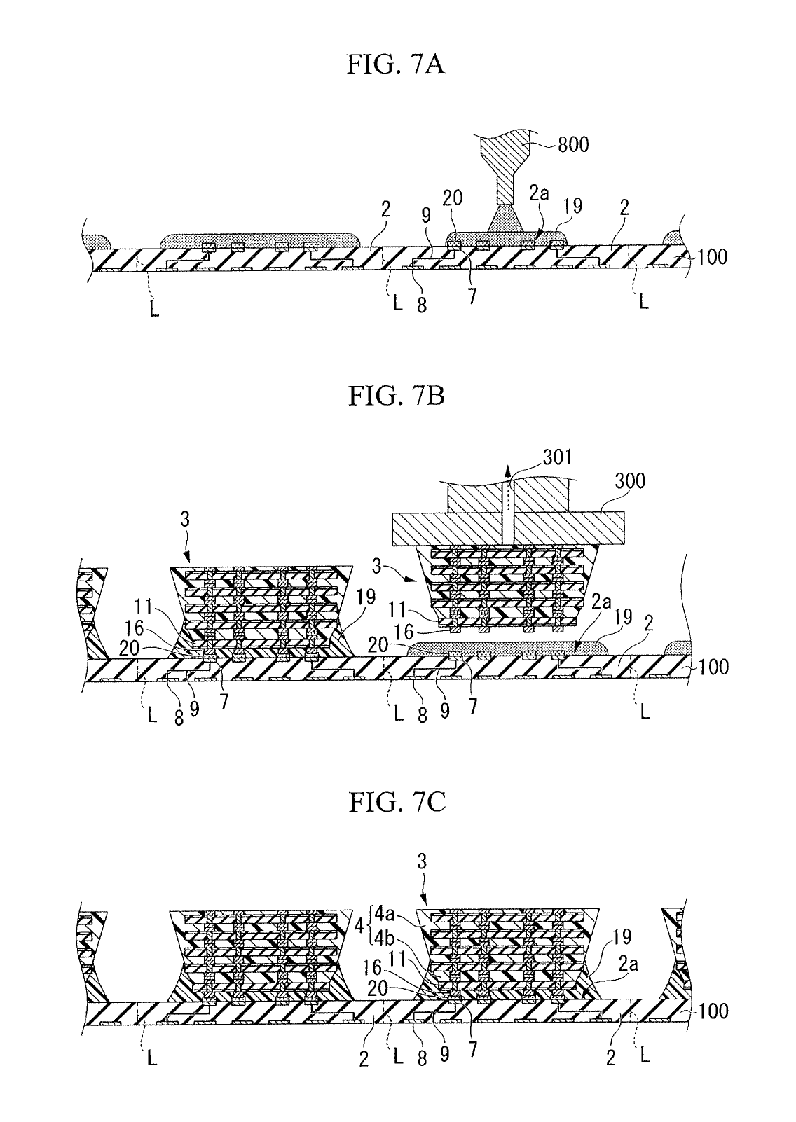

As shown in FIG. 7A to FIG. 7C, a mother wiring substrate 100 formed by arranging a plurality of parts serving as the wiring substrates 2 is prepared. The mother wiring substrate 100 is made of, for example, a glass epoxy wiring substrate having a thickness of approximately 0.14 mm, and is formed by arranging in a matrix shape the plurality of parts serving as the wiring substrates 2, and also finally by cutting thereof along the dicing line L, and it is possible to cut out the parts to be the wiring substrates 2 as each of the wiring substrates 2. Also, the wire bumps to serve as the above-noted second bonding members 20 are placed on each of the pad electrodes 7 of the parts to serve as the wiring substrates 2.

The chip stack 3 is mounted over the entire surface of the mother wiring substrate 100 for each part to serve as the wiring substrates 2. Specifically, as shown in FIG. 7A, a dispenser 800 that supplies a liquid-state adhesive member 19 known as an NCP (non-conductive paste) is used to apply the liquid-state adhesive members 19 onto the mother wiring substrate 100 for each of mounting regions 2a of parts to serve as the wiring substrates 2.

From this condition, as shown in FIG. 7B, the bonding tool 300 is used to flip-chip mount the chip stack 3 onto the mounting region 2a of the parts to serve as the wiring substrate 2 of the mother wiring substrate 100. In this flip-chip mounting, the vacuum hole 301 in the bonding tool 300 vacuum chucks the chip stack 3 as the bonding tool 300 holds the chip stack 3, with the logic chip 11 facing downward.

The bonding tool 300 places the chip stack 3 on top of the mounting region 2a of the parts to serve as the wiring substrate 2, while causing the logic chip 11 to oppose the mounting region 2a of the parts to be the wiring substrate 2, with the positions of the fourth bump electrodes 16 and a pad electrodes 7 therebetween aligned. In this condition, the bonding tool 300 applies a load while heating at a temperature of approximately 300° C. to bond by heat bonding (flip-chip bonding) the fourth bump electrodes 16 and the pad electrodes 7, via the second bonding members (wiring bumps) 20.

When this bonding is done, not only a load, but ultrasonic waves as well may be applied.

By doing this, electrical connections (flip-chip connections) are made between the fourth bump electrodes 16 and the pad electrodes 7 via the second bonding members (wiring bumps) 20, and the chip stack 3 is flip-chip mounted onto the mounting region 2a of the parts serving as the wiring substrate 2 of the mother wiring substrate 100.

Also, the adhesive member 19 hardens, as shown in FIG. 7C, in the condition in which it oozes out from between the one surface of the wiring substrate 2 and the other surface of the logic chip 11. By doing this, the chip stack 3 is bonded so as to be fixed onto the mounting region 2a of the parts serving as the wiring substrate 2 of the mother wiring substrate 100 via the adhesive member 19.

In the first sealing element 4 (the first underfilling material 4a and the second underfilling material 4b) that seals the chip stack 3, the width of the first and second underfilling materials 4a and 4b that oozes from the gaps of the chip stack 3 gradually becomes wider from the lower layer side toward the upper layer side, and has a so-called a reverse taper shape. In this case, because the adhesive member 19 that oozes out from between the one surface of the wiring substrate 2 and the other surface of the logic chip 11 is suppressed from creeping upward, it is possible to reduce an occurrence of cracks, bonding failures, or the like of the chip stack 3 caused by the attachment of the adhesive member 19 onto the bonding tool 300.

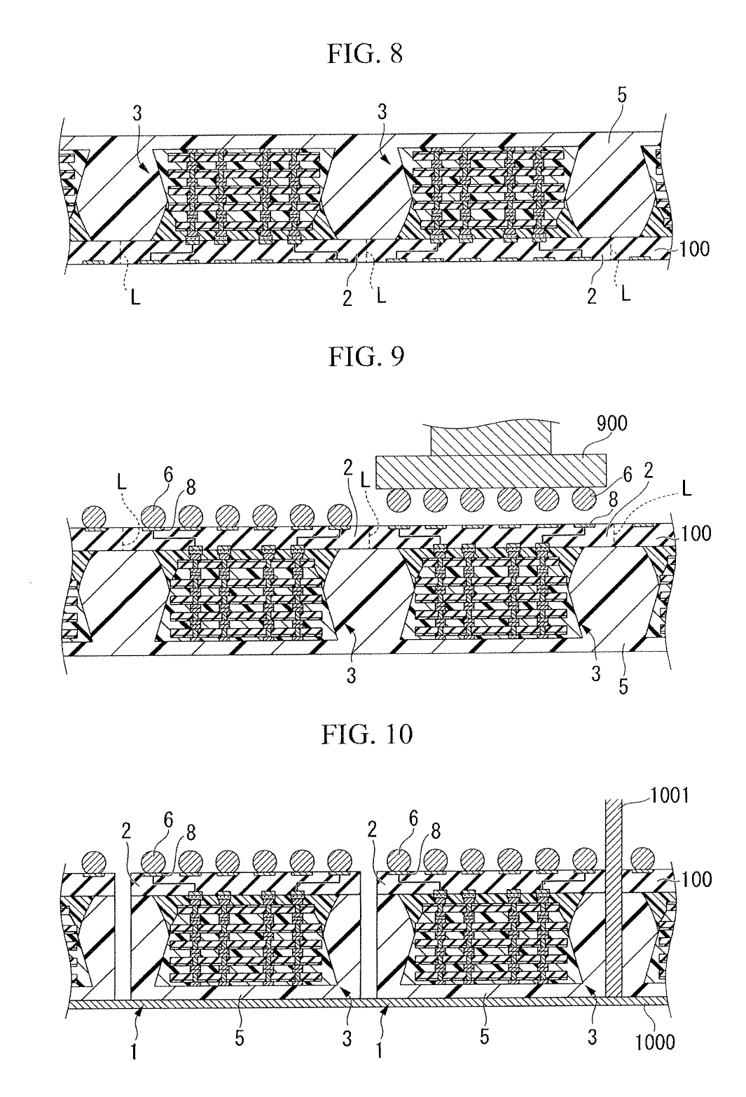

As shown in FIG. 8, the one surface side of the mother wiring substrate 100 is sealed by a mold resin that will serve as the above-noted second sealing element 5, so as to cover the chip stack 3. Specifically, a transfer molding machine (not shown in the drawings) is used. The transfer molding machine has a pair of shaping molds, made of a lower mold (fixed) that holds the other surface side of the mother wiring substrate 100 and forms a cavity space that is filled with the molding resin and that opposes the one surface side of the mother wiring substrate 100, and also an upper mold (movable) that moves relative the lower mold to join or to separate freely with respect to the lower mold.

The mother wiring substrate 100 mounting the chip stack 3 is set onto the shaping mold of the transfer molding machine, and then a heated and melted molding resin is poured into the cavity space within the shaping mold. A heat-cured resin, such as an epoxy resin, is used as this molding resin.

Under this condition, by heating (curing) the mold resin at a prescribed temperature (for example, approximately 180° C.), the molding resin is caused to harden. Additionally, by baking at a prescribed temperature, the mold resin is caused to harden completely. By doing this, the one surface side of the mother wiring substrate 100 is completely sealed by the molding resin serving as the above-noted second sealing element 5.

In the present invention, as above-described, stack 3 of a plurality of the chips that is sealed by the first sealing element 4 (the first underfilling material 4a and the second underfilling material 4b) is mounted onto the mother wiring substrate 100, and then the second sealing element 5 totally seals the top of the mother wiring substrate 100, thereby enabling reduction of the occurrence of voids (air bubbles).

As shown in FIG. 9, the above-noted solder balls 6 are placed over the bonding lands 8 that are formed in the parts to serve as the wiring substrates 2 of the mother wiring substrate 100. A mounting tool 900 of a ball mounter forming a plurality of vacuum holes (not shown in drawings) is used to chuck and hold a plurality of solder balls 6 by the mounting tool 900, while flux is transferred and formed onto the plurality of solder balls 6, after which the solder balls 6 are placed onto the bonding lands 8 for each part to serve as the wiring substrates 2 of the mother wiring substrate 100. After the solder balls 6 are placed onto the parts to serve as the entire wiring substrates 2 of the mother wiring substrate 100, the mother wiring substrate 100 is reflowed. By doing this, the solder balls 6 are placed onto the bonding lands 8 of the parts to be the wiring substrates 2 of the mother wiring substrate 100.

As shown in FIG. 10, the mother wiring substrate 100 is cut into the parts to serve as the wiring substrate 2 so as to be divided into each individual semiconductor package 1. Specifically, after a dicing tape 1000 is adhered onto the second sealing element 5 side of the mother wiring substrate 100, the mother wiring substrate 100 is cut along the dicing line L from the opposite side with respect to the dicing tape 1000, using a dicing blade 1001. By doing this, separation is done into each semiconductor package 1. The semiconductor packages 1 are peeled away from the dicing tape 1000, thereby enabling obtainment of the semiconductor package 1 as shown in the FIG. 1A.

As described above, in the method for manufacturing the semiconductor package 1 to which the present invention is applied, by the interposing of the first bonding member 18 between the third bump electrodes 15 of the logic chip 11 and the second bump electrodes 13 of the memory chip 10d therebelow, it is possible to achieve a good bond between the bump electrodes 13 and 15 of the memory chip 10d and the logic chip 11, which are difficult to bond with heat, without a restriction on the electrode material or bonding method.

The present invention is not necessarily limited to the above-noted embodiments, and various changes are possible within the scope of and without departing from the spirit of the present invention. In the following description, the descriptions of similar parts of the above-noted semiconductor package 1 are omitted herein, and in the drawings the same reference numerals are assigned.

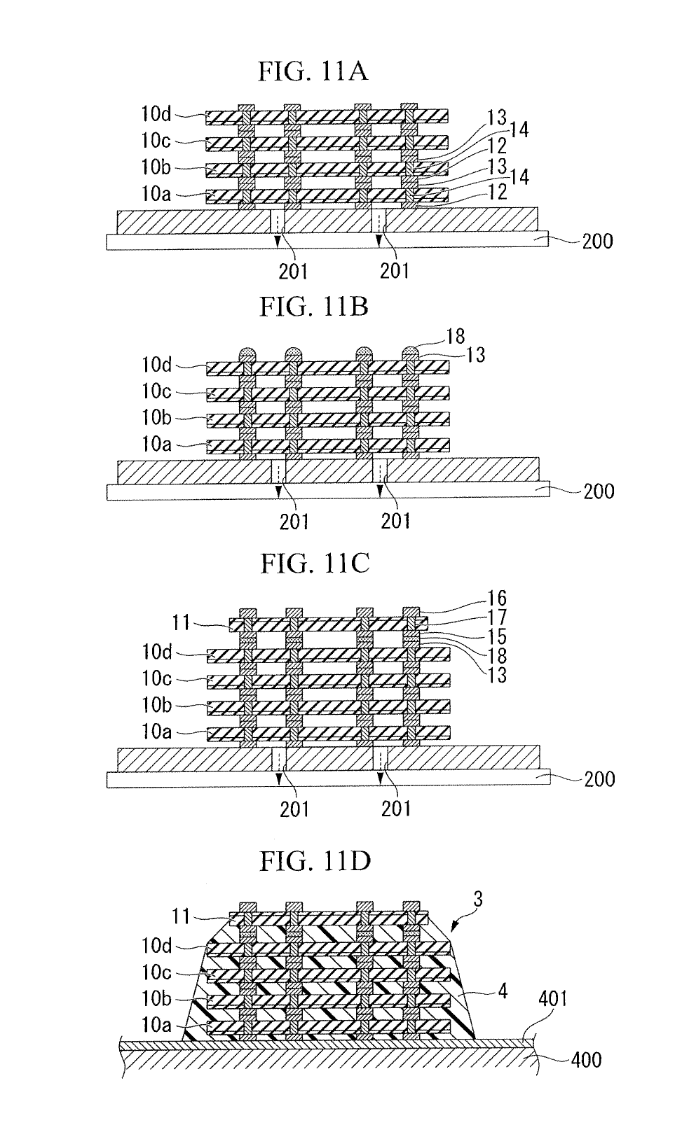

For example, in the present invention, as shown in FIG. 11A to FIG. 11D, after a plurality of the memory chips 10a to 10d and the logic chip 11 are stacked, the underfilling material to serve as the above-noted first sealing element 4 may be filled between the gaps in the stack. When this is done, it is possible to simplify the manufacturing process.

As shown in FIG. 11A, similar to the case shown in the above-noted FIG. 2A to FIG. 2C, a plurality of the memory chips 10a to 10d over the vacuum chuck stage 200 are caused to have the one surfaces to oppose the other corresponding surfaces, and are stacked by the first bump electrodes 12 and the second bump electrodes 13 therebetween being bonded.

As shown in FIG. 11B, similar to the case shown in the above-noted FIG. 4A to FIG. 4C, the first bonding members 18 are placed on top of the second bump electrodes 13 in the memory chip 10d placed at the uppermost layer.

As shown in FIG. 11C, similar to the case shown in the above-noted FIGS. 5A and 5B, while causing the one surface of the logic chip 11 to oppose the other surface of the memory chip 10d beneath it, after the second bump electrode 13 and the third bump electrode 15 therebetween are bonded and stacked via the first bump member 18, the bonding tool 300 (not shown in the drawing) is moved in the upper direction as the gap between the logic chip 11 and the fourth the memory chip 10d is widened.

As shown in FIG. 11D, the underfilling material is filled between the gaps of the stacks in which the above-noted plurality of the memory chips 10a to 10d and the logic chip 11 are stacked, and the chip stack 3 is sealed by the underfilling material (the first sealing element 4).

Also, in the above-noted embodiment, although the chip stack 3 is mounted onto the mother wiring substrate 100 after the adhesive member 19 is applied onto the mother wiring substrate 100, the adhesive member 19 may be filled between the mother wiring substrate 100 and the chip stack 3 after the chip stack 3 is mounted onto the mother wiring substrate 100. When doing this, the fourth bump electrodes 16 of the logic chip 11 are formed high to ensure a gap between the chip stack 3 and the mother wiring substrate 100 wide, so that it is possible to improve the filling of the adhesive member 19.

Although the above-noted chip stack 3 is constituted by stacking four memory chips 10a to 10d and the logic chip 11, the number of stacking of the memory chips may be two or more, and it is not necessarily limited to this constitution.

Also, although the above-noted chip stack 3 is constituted by combining memory chips and a logic chip, the present invention may be applied to any combination of chips, providing, in the chip stacks, that different kinds of devices are directly connected, and may be applied to a combination of a device chip and a silicon interposer.

Also, the present invention is applicable not only to the above-noted BGA-type semiconductor package 1, but also to other semiconductor packages, such as an LGA (land grid array) or a CSP (chip-size package) type.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a wiring board;
a first semiconductor chip disposed over the wiring board;
a stack of second semiconductor chips disposed over the first semiconductor chip; and
a first connection structure connecting the first semiconductor chip and the stack of second semiconductor chips,
the first connection structure comprising:
first and second connection electrodes disposed on the first semiconductor chip and a closest second semiconductor chip of the stack, respectively, the closest second semiconductor chip being closest to the first semiconductor chip; and
a first bonding material bonding the first and second connection electrodes.

2. The semiconductor device according to claim 1, wherein at least one of the second and third bump electrodes has at least a depression which is filled with the first bonding material.

3. The semiconductor device according to claim 1, wherein the first bonding material comprises a solder.

4. The semiconductor device according to claim 1, wherein the first semiconductor chip is different in type from the second semiconductor chip.

5. The semiconductor device according to claim 1, wherein the first semiconductor chip is a logic chip, and the second semiconductor chip is a memory chip which is larger in dimension than the logic chip.

6. The semiconductor device according to claim 1, further comprising:
a third connection electrode on the first semiconductor chip; and
a first through electrode penetrating the first semiconductor chip, the first through electrode connecting the first and third connection electrodes,
wherein the first and third connection electrodes are disposed on opposite surfaces of the first semiconductor chip.

7. The semiconductor device according to claim 6, wherein the third connection electrode is greater in height than the first connection electrode.

8. The semiconductor device according to claim 6, further comprising:
a fourth connection electrode on the wiring board; and
a second bonding material between the third and fourth connection electrodes, the second bonding material bonding the third and fourth connection electrodes.

9. The semiconductor device according to claim 1, further comprising:
an adhesive material between the wiring board and the first semiconductor chip.

10. The semiconductor device according to claim 9, further comprising:
a first sealing material that fills a first gap between the first and second semiconductor chips and second gaps between the second semiconductor chips included in the stack; and
a second sealing material covering the adhesive material and the first sealing material.

11. A semiconductor device comprising:
a wiring board including a plurality of pad electrodes thereon;
a first semiconductor chip including a plurality of first bump electrodes on a first surface, a plurality of second bump electrodes on a second surface opposed to the first surface, and a plurality of first through electrodes electrically coupled the first bump electrodes to the second bump electrodes, and the first semiconductor chip mounted over the wiring board so that the first bump electrodes are electrically coupled to the pad electrodes of the wiring board;
a chip stack including a plurality of second semiconductor chips that are stacked one another, the chip stack including a plurality of third bump electrodes on lowermost one of the second semiconductor chips, and the chip stack mounted over the first semiconductor chip so that the lowermost one of the second semiconductor chips faces the first semiconductor chip; and
a plurality of first bonding materials provided between the plurality of second bump electrodes and the plurality of third bump electrodes, the plurality of first bonding materials bonding the plurality of second bump electrodes and the plurality of third bump electrodes.

12. The semiconductor device according to claim 11, wherein at least one of the second and third bump electrodes has at least a depression which is filled with the first bonding material.

13. The semiconductor device according to claim 11, wherein the plurality of second semiconductor chips includes a plurality of through electrodes, each of the second semiconductor chips are electrically coupled one another via the through electrodes.

14. The semiconductor device according to claim 11, further comprising:
a plurality of second bonding materials provided between the plurality of pad electrodes and the plurality of first bump electrodes, the plurality of second bonding materials bonding the plurality of pad electrodes and the plurality of first bump electrodes.

15. The semiconductor device according to claim 11, further comprising:
a first sealing material that fills a first gap between the first semiconductor chip and the chip stack and a second gap between the plurality of second semiconductor chips of the chip stack.

16. The semiconductor device according to claim 11, wherein the first semiconductor chip is different in type from the second semiconductor chips of the chip stack.

17. A semiconductor device comprising:
a first semiconductor chip;
a first connection electrode on the first semiconductor chip;
a second semiconductor chip stacked over the first semiconductor chip;
a second connection electrode on the second semiconductor chip; and
a first bonding material between the first and second connection electrodes, the first bonding material bonding the first and second connection electrodes,
wherein at least one of the first and second connection electrodes has at least a depression which is filled with the first bonding material.

18. The semiconductor device according to claim 17, wherein the depression is positioned at a center of the at least one of the first and second connection electrodes.

19. The semiconductor device according to claim 17, further comprising:
a wiring board on which the first semiconductor chip is stacked;
a third connection electrode on the first semiconductor chip, the third connection electrode being greater in height than the first connection electrode, the first and third connection electrodes being disposed on opposite surfaces of the first semiconductor chip;
a first through electrode penetrating the first semiconductor chip, the first through electrode connecting the first and third connection electrodes;
a fourth connection electrode on the wiring board; and
a second bonding material between the third and fourth connection electrodes, the second bonding material bonding the third and fourth connection electrodes.

20. The semiconductor device according to claim 19, further comprising:
a third semiconductor chip stacked on the second semiconductor chip;
a fifth connection electrode on the second semiconductor chip, the second and fifth connection electrodes being disposed on opposite surfaces of the second semiconductor chip;
a sixth connection electrode on the third semiconductor chip, the sixth connection electrode being in contact with the fifth connection electrode; and
a second through electrode penetrating the second semiconductor chip, the second through electrode connecting the second and fifth connection electrodes.
